(19) United States
(12) Patent Application Publication
(10) Pub. No.: US 2010/0155920 A1
(43) Pub. Date: Jun. 24, 2010

(54) Stacked semiconductor package, semiconductor package module and method of manufacturing the stacked semiconductor package

(75) Inventor: Tae-young Lee, Incheon (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,820

(22) Filed: Dec. 2, 2009

(30) Foreign Application Priority Data
Dec. 24, 2008 (KR) 10-2008-0133837

(51) Int. Cl. H01L 25/065

(52) U.S. Cl. 257/686; 257/690; 257/737; 257/E25.013

(57) ABSTRACT

Provided are a stacked-type semiconductor package using a stud bump, a semiconductor package module, and a method of fabricating the stacked-type semiconductor package. The stacked-type semiconductor package may include a first semiconductor package and a second semiconductor package stacked on the first semiconductor package. The first semiconductor package may include a first circuit board and at least one conductive member extending upward from the first circuit board. The second semiconductor package may include a second circuit board, and a stud bump being inserted from the second circuit board into the at least one conductive member of the first semiconductor package in order to electrically connect the first semiconductor package and the second semiconductor package.

### CROSS-REFERENCE TO RELATED APPLICATIONS

This application claims priority under 35 U.S.C. §119 to Korean Patent Application No. 10-2008-0133837, filed on Dec. 24, 2008, in the Korean Intellectual Property Office (KIPO), the entire contents of which are herein incorporated by reference.

### BACKGROUND

1. Field

Example embodiments relate to a semiconductor device and a method of fabricating the same, and more particularly, to a stacked-type semiconductor package using stud bumps and a method of fabricating the same.

2. Description of the Related Art

As electronic portable devices become smaller and/or thinner, semiconductor packages may be required to be smaller, thinner, and lighter. Thus, stacked-type semiconductor packages manufactured by stacking a plurality of semiconductor packages together have been used. In the stacked-type semiconductor package, forming a reliable electrical connection between stacked semiconductor packages may be important. Increasing the total number of external connection terminals for performing multi-functions may also be important.

### SUMMARY

Example embodiments relate to a semiconductor device and a method of fabricating the same, and more particularly, to a stacked-type semiconductor package using stud bumps and a method of fabricating the same.

In accordance with example embodiments, a stacked-type semiconductor package may include a first semiconductor package including a first encapsulating member having at least one first via-hole and at least one first conductive member in the at least one first via-hole and a second semiconductor package including at least one first stud bump, wherein the at least one first stud bump protrudes into the at least one first via-hole to electrically connect the first semiconductor package and the second semiconductor package.

In accordance with example embodiments, a method of fabricating a stacked-type semiconductor package may include providing a first semiconductor package having a first semiconductor chip on a first circuit board and an encapsulant on the first semiconductor chip and the first circuit board, forming at least one via-hole through the encapsulant to expose a portion of the first circuit board, filling the at least one via-hole with a conductive material, providing a second semiconductor package having a second semiconductor chip on a second circuit board, forming at least one stud bump on a surface of the second circuit board, aligning the at least one stud bump with the at least one via-hole by stacking the second semiconductor package on the first semiconductor package, electrically connecting the first and second semiconductor packages by moving the at least one stud bump into contact with the conductive material.

According to example embodiments, a stacked-type semiconductor package may include a first semiconductor package and a second semiconductor package stacked on the first semiconductor package. The first semiconductor package may include a first circuit board, a first semiconductor chip mounted on the first circuit board, and a first encapsulating member disposed on the first circuit board to cover the first semiconductor chip, where at least one via-hole may be formed in the first encapsulating member. At least one conductive member may be disposed in the at least one via-hole. In accordance with example embodiments, the at least one conductive member may extend upward from the first circuit board. The second semiconductor package may include a second circuit board and at least one stud bump inserted from the second circuit board into the at least one conductive member of the first semiconductor package to electrically connect the first semiconductor package and the second semiconductor package.

Each of the at least one stud bump may include a bonding portion connected to a substrate land of the second circuit board and a protruding portion extending from the bonding portion into the at least one via-hole.

The area of a part of the bonding portion, which may be connected to the substrate land, may be greater than the area of the protruding portion.

The stacked-type semiconductor package may further include a third semiconductor package stacked on the second semiconductor package. The second semiconductor package may further include a second semiconductor chip mounted on the second circuit board and a second encapsulating member disposed on the second circuit board to cover the second semiconductor chip. At least one second via-hole may be formed in the second encapsulating member and at least one second conductive member may be disposed in the at least one second via-hole. The at least one second conductive member may extend upward from the second circuit board. The third semiconductor package may include a third circuit board and at least one second stud bump extending from the third circuit board into at least one second conductive member of the second semiconductor package to electrically connect the second semiconductor package and the third semiconductor package.

According to example embodiments, a semiconductor package module may include a module substrate, at least one lower semiconductor package mounted on the module substrate, and at least one upper semiconductor package stacked on the at least one lower semiconductor package. The at least one lower semiconductor package may include a first circuit board including at least one substrate pad, a first semiconductor chip mounted on the first circuit board, and a first encapsulating member disposed on the first circuit board to cover the first semiconductor chip, wherein at least one via-hole is formed in the first encapsulating member to expose the at least one substrate pad and at least one conductive member is disposed in the at least one via-hole, and contacting the at least one substrate pad. The at least one upper semiconductor package may include a second circuit board having a substrate land and at least one stud bump extending from the substrate land of the second circuit board into the at least one conductive member of the first semiconductor package to electrically connect the first semiconductor package and the second semiconductor package.

### BRIEF DESCRIPTION OF THE DRAWINGS

Example embodiments will be more clearly understood from the following detailed description, taken in conjunction with the accompanying drawings in which:

FIG. 1 is a schematic cross-sectional view of a stacked-type semiconductor package according to example embodiments;

FIG. 2 is a schematic cross-sectional view of a stacked-type semiconductor package according to example embodiments;

FIG. 3 is a schematic cross-sectional view of a stacked-type semiconductor package according to example embodiments;

FIGS. 4 to 9 are cross-sectional views for describing a method of forming a stacked-type semiconductor package, according to example embodiments;

FIGS. 10A to 10C are perspective views a stud bump according to example embodiments;

FIG. 11 is a schematic cross-sectional view of a semiconductor package module according to example embodiments;

FIG. 12 is a schematic cross-sectional view of a semiconductor package module according to example embodiments; and

FIG. 13 is a block diagram of an electronic system according to example embodiments.

### DETAILED DESCRIPTION OF THE EMBODIMENTS

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

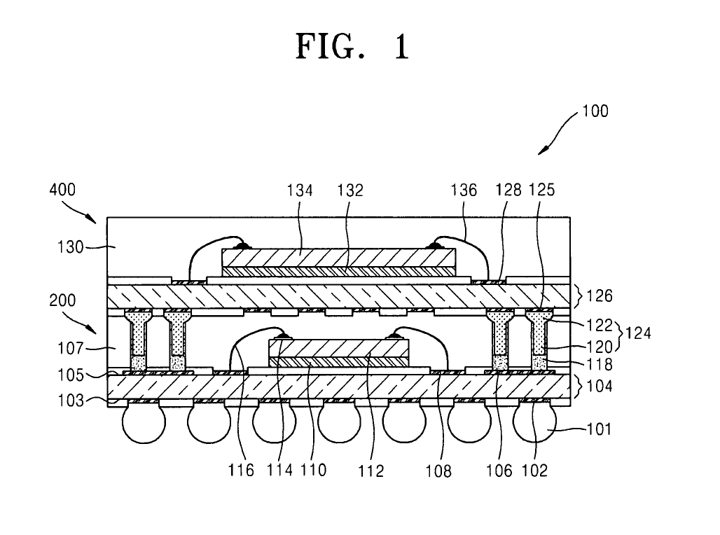

FIG. 1 is a schematic cross-sectional view of a stacked-type semiconductor package 100 according to example embodiments. Referring to FIG. 1, the stacked-type semiconductor package 100 may include a first semiconductor package 200 and a second semiconductor package 400. The second semiconductor package 400 may be stacked on the first semiconductor package 200. The first semiconductor package 200 and the second semiconductor package 400 may perform the same functions or different functions. For example, the stacked-type semiconductor package 100 may be referred to as a package-on-package (POP) type package, however, example embodiments are not limited thereto.

The first semiconductor package 200 may include a first circuit board 104 having a top surface 105 and a bottom surface 103. The first circuit board 104 may be either a rigid substrate or a flexible substrate. For example, the circuit board 104 may be formed of flame retardant 4 (FR4) resin or bismaleimide-triazine (BT) resin. Examples of the first circuit board 104 may include a printed circuit board (PCB), a liquid crystal polymer (LCP) film, and a polyimide (PI) film.

The first circuit board 104 may include at least one substrate land 102 on the bottom surface 103. The first circuit board 104 may also include at least one substrate pad 106 and at least one internal pad 108 on the top surface 105. The at least one substrate pad 106 may be used to connect the second semiconductor package 400 to an external device, and the at least one internal pad 108 may be used for internal interconnection in the first semiconductor package 200. The at least one substrate pad 106 and the at least one internal pad 108 may be formed using the same material according to the same method. The at least one substrate land 102, the at least one substrate pad 106, and the at least one internal pad 108 may be appropriately connected via a circuit interconnection unit (not shown) in the first circuit board 104.

A first semiconductor chip 112 may be mounted on the first circuit board 104 via a first adhesive layer 110. For example, the first semiconductor chip 112 may include a memory chip and/or a logic chip. As another example, the first semiconductor chip 112 may include two or more of the same or different types of semiconductor chips. The first semiconductor chip 112 may include a chip pad 114 connected to an internal circuit (not shown), and the chip pad 114 and the at least one internal pad 108 may be connected via first wires 116.

A first encapsulating member 107 may be formed on the first circuit board 104 in order to protect the first semiconductor chip 112 and the first wires 116. For example, the first encapsulating member 107 may be formed to cover exposed portions of the first semiconductor chip 112 and the first wires 116. The first encapsulating member 107 may include an insulating resin, e.g., an epoxy molding compound (EMC). The first encapsulating member 107 may include at least one via-hole 140, as illustrated in FIG. 4, in order to expose portions of the at least one substrate pad 106.

At least one conductive member 118 may be disposed in the at least one via-hole 140. The at least one conductive member 118 may extend upward from the at least one substrate pad 106. For example, the conductive member 118 may substantially extend perpendicularly to the first circuit board 104. The conductive member 118 may include solder material and may contact the at least one substrate pad 106. The height of the conductive member 118 may be less than or equal to that of the at least one via-hole 140.

A solder ball 101 may be formed on the at least one substrate land 102. The solder ball 101 may be provided to connect the stacked-type semiconductor package 100 to an external device but may be omitted according to the usage of the stacked-type semiconductor package 100.

The second semiconductor package 400 may include a second circuit board 126. At least one internal pad 128 and at least one substrate land 125 may be respectively formed on top and bottom surfaces of the second circuit board 126. The second circuit board 126 is as described above for the above first circuit board 104.

A second semiconductor chip 134 may be mounted on the second circuit board 126 via a second adhesive layer 132. The second semiconductor chip 134 may include at least one semiconductor chip which may be identical to or different from that of the first semiconductor chip 112. The second semiconductor chip 134 may be connected to the second circuit board 126 via second wires 136. For example, one end of the second wires 136 may be bonded to the at least one internal pad 128. A second encapsulating member 130 may be disposed on the second circuit board 126 in order to cover the second semiconductor chip 134 and the second wires 136. The second encapsulating member 130 is as described above for the first encapsulating member 107.

A stud bump 124 may be formed on the at least one substrate land 125. The stud bump 124 may extend downward from the at least one substrate land 125 into the via-hole 140 I which the conductive member 118 of the first semiconductor package 200 is disposed. The stud bump 124 may be combined with the conductive member 118, thereby connecting the first semiconductor package 200 to the second semiconductor package 400.

For example, the stud bump 124 may include a protruding portion 120 and a bonding portion 122. The bonding portion 122 may be bonded to the at least one substrate land 125, and the protruding portion 120 may extend downward from the bonding portion 122 to contact the conductive member 118. For example, the bonding portion 122 may have a hemispherical shape, and the protruding portion 120 may have a cylindrical shape. In order to increase the bonding strength between the stud bump 124 and the conductive member 118, the bottom of the protruding portion 120 may be inserted into the conductive member 118. In example embodiments, the height of the protruding portion 120 may be less than that of the at least one via-hole 140 of the first semiconductor package 200. As shown in FIG. 1, the lower sidewalls and bottom surface of the protruding portion 120 may be encompassed with the conductive member 118. Thus, the stud bump 124 may be combined with the conductive member 118 by being inserted into the conductive member 118. As a result, the contact area between the protruding portion 120 and the conductive member 118 may increase which may improve the bonding strength between the stud bump 124 and the conductive member 118.

As described above, the thickness of the stacked-type semiconductor package 100 may be reduced by inserting the stud bumps 124 of the second semiconductor package 400, that is, the upper-half part of the stacked-type semiconductor package 100, respectively into the via-holes 140 of the first semiconductor package 200, that is, the lower-half part of the stacked-type semiconductor package 100. Also, the stud bump 124 may be combined with the conductive member 118 by being inserted into the conductive member 118, therefore reliability of connection between the first semiconductor package 200 and the second semiconductor package 400 may be improved. Accordingly, the operating reliability of the stacked-type semiconductor package 100 may be improved.

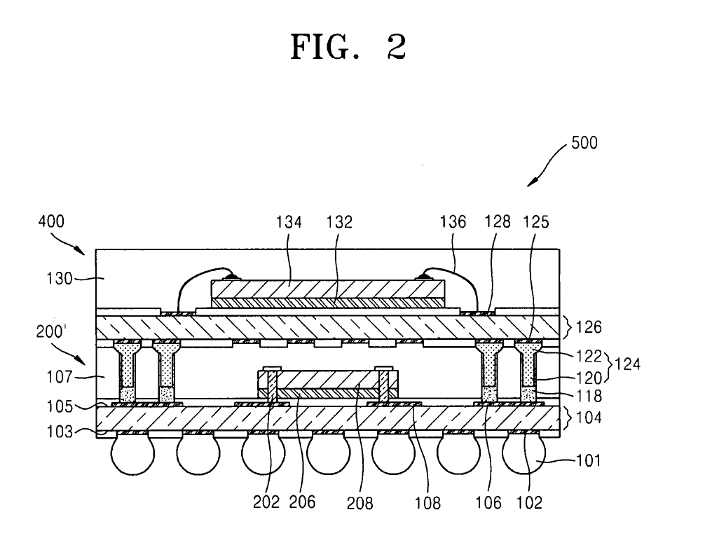

FIG. 2 is a schematic cross-sectional view of a stacked-type semiconductor package 500 according to example embodiments. The stacked-type semiconductor package 500 may be obtained by partially modifying the stacked-type semiconductor package 100 of FIG. 1. Thus, a description of elements of the stacked-type semiconductor package 500 that are the same as those of the stacked-type semiconductor package 100 will not be provided hereafter.

Referring to FIG. 2, the stacked-type semiconductor package 500 may include a first semiconductor package 200′, and a second semiconductor package 400 on the first semiconductor package 200′. A first semiconductor chip 208 may be mounted on the first circuit board 104 via an adhesive layer 206. Unlike the stacked-type semiconductor package 100 illustrated in FIG. 1, the first semiconductor chip 208 of the stacked-type semiconductor stacked package 500 may be connected to the at least one internal pad 108 via a through-electrode 202. The through-electrode 202 may be disposed to pass through the first semiconductor chip 208 in order to reduce the height of the first encapsulating member 107, thereby reducing the thickness of the first semiconductor package 200′. If the first semiconductor package 200′ has a multi chip package (MCP) structure, the through-electrode 202 may be useful to reduce the thickness of the first semiconductor package 200′.

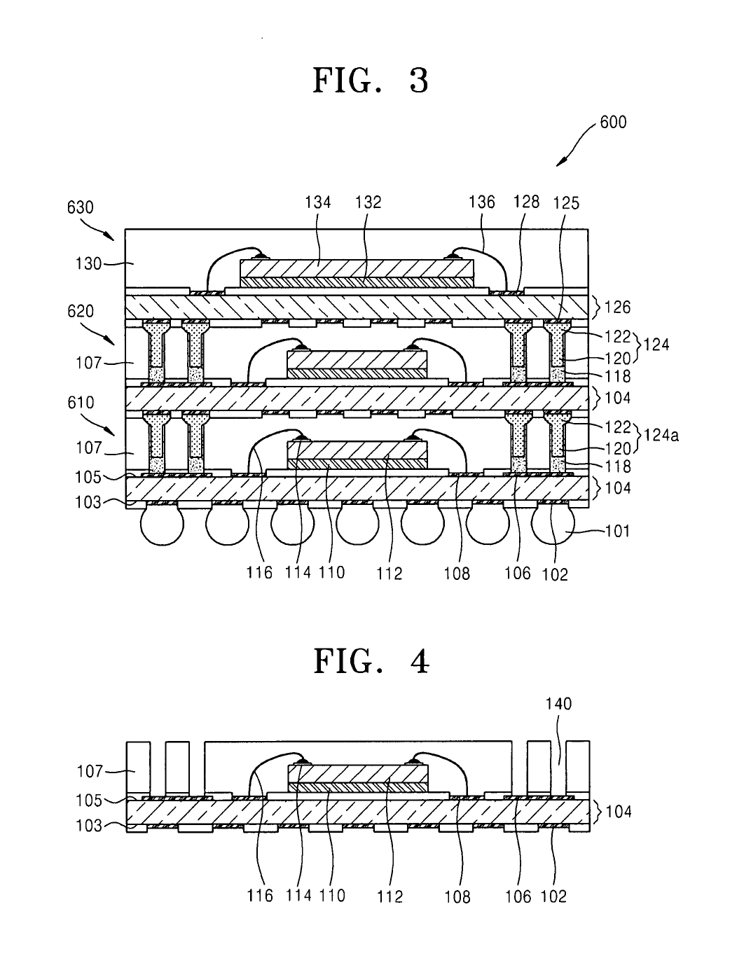

FIG. 3 is a schematic cross-sectional view of a stacked-type semiconductor package 600 according to example embodiments. Referring to FIG. 3, in the stacked-type semiconductor package 600, a second semiconductor package 620 and a third semiconductor package 630 may be sequentially stacked on a first semiconductor package 610. Alternatively, a plurality of semiconductor packages (not shown) may be included between the first semiconductor package 610 and the second semiconductor package 620.

The first semiconductor package 610 may substantially have the same structure as the first semiconductor package 200 of FIG. 1. The third semiconductor package 630 may substantially have the same structure as the second semiconductor package 400 of FIG. 1.

The second semiconductor package 620 may be similar to the first semiconductor package 200 of FIG. 1. However, the second semiconductor package 620 may include a stud bump 124a, which is similar to the stud bump 124 of the second semiconductor package 400, instead of the solder ball 101 of the first semiconductor package 200.

The conductive member 118 of the first semiconductor package 610 and the conductive member 118 of the second semiconductor package 620 may be respectively connected to the stud bump 124a of the second semiconductor package 620 and the stud bump 124 of the third semiconductor package 630. Thus, the first semiconductor package 610, the second semiconductor package 620, and the third semiconductor package 630 may be connected to one another.

FIGS. 4 to 9 are cross-sectional views for describing an example method of forming a stacked-type semiconductor package, according to example embodiments. Referring to FIGS. 4 to 7, a first semiconductor package 200 may be prepared. For example, as illustrated in FIG. 4, the first semiconductor chip 112 may be mounted on the first circuit board 104, and the first semiconductor chip 112 and the first circuit board 104 may be connected via the first wires 116. The first encapsulating member 107 may be formed on the first circuit board 104 to cover the first semiconductor chip 112 and the first wires 116. The resultant structure may be manufactured or may be purchased from an outside manufacturer. The at least one via-hole 140 may be formed in the first encapsulating member 107 in order to expose parts of the substrate pad 106. The via-hole 140 may be formed by laser drilling or using photolithographic and etching processes. For example, the etching process may be a dry or wet etching process.

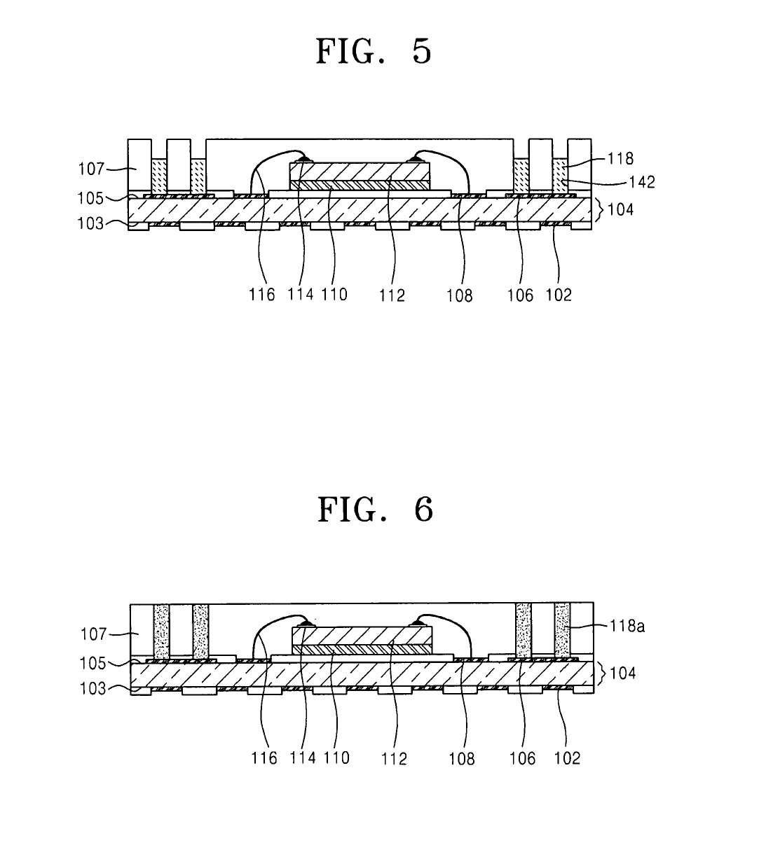

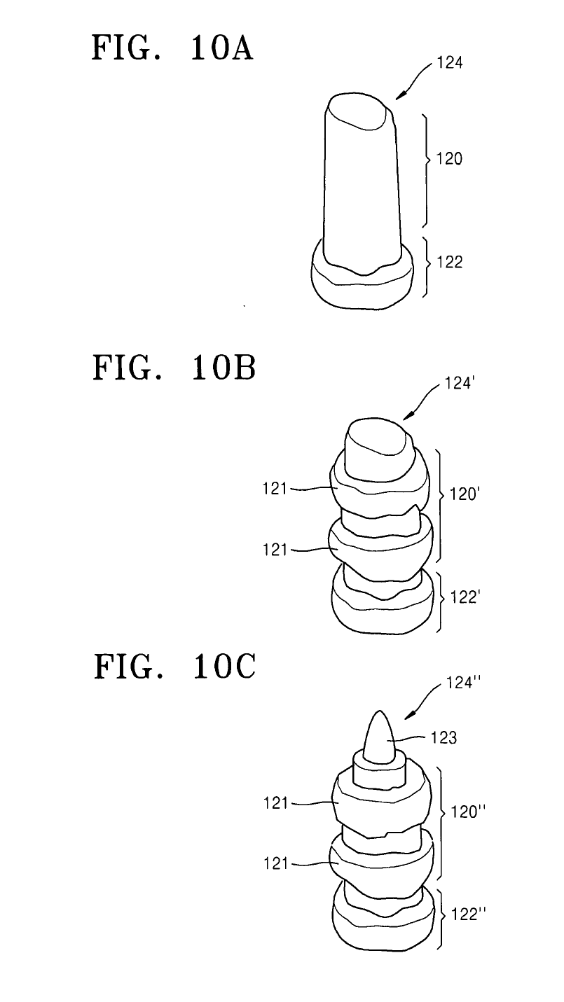

Referring to FIG. 5, the conductive member 118 may be obtained by filling the at least one via-hole 140 with a conductive material 142 and hardening the at least one via-hole 140 through thermal processing. For example, the conductive material 142 may be a solder paste. The height of the conductive member 118 may be determined to be less than that of the at least one via-hole 140, in consideration of the whole volume of the stud bump 124, as shown in FIG. 10a, which may be inserted into the at least one via-hole 140. For example, the at least one via-hole 140 may be filled with the solder paste of which the amount is less than a predetermined or preset level in order to prevent or retard the solder paste from overflowing when the stud bump 124 is inserted into the via-hole 140. For example, if the volume of the stud bump 124 occupies 30% of that of the via-hole 140, then preventing or retarding the solder paste from overflowing may be possible by filling 70% or less of the at least one via-hole 140 with the solder paste.

Alternatively, as illustrated in FIG. 6, a conductive member 118a may be formed in the at least one via-hole 140 so that the at least one via-hole 140 may be almost filled with the conductive member 118a. For example, the conductive member 118a may be formed of solder powder. Because the volume of the conductive member 118a may decrease during a subsequent hardening process, the conductive member 118a may be first formed so that the at least one via-hole 140 may be completely filled with the conductive member 118a. Optionally, as illustrated in FIG. 3, only a part of the at least one via-hole 140 may be filled with the conductive member 118 in consideration of the volume of the stud bump 124.

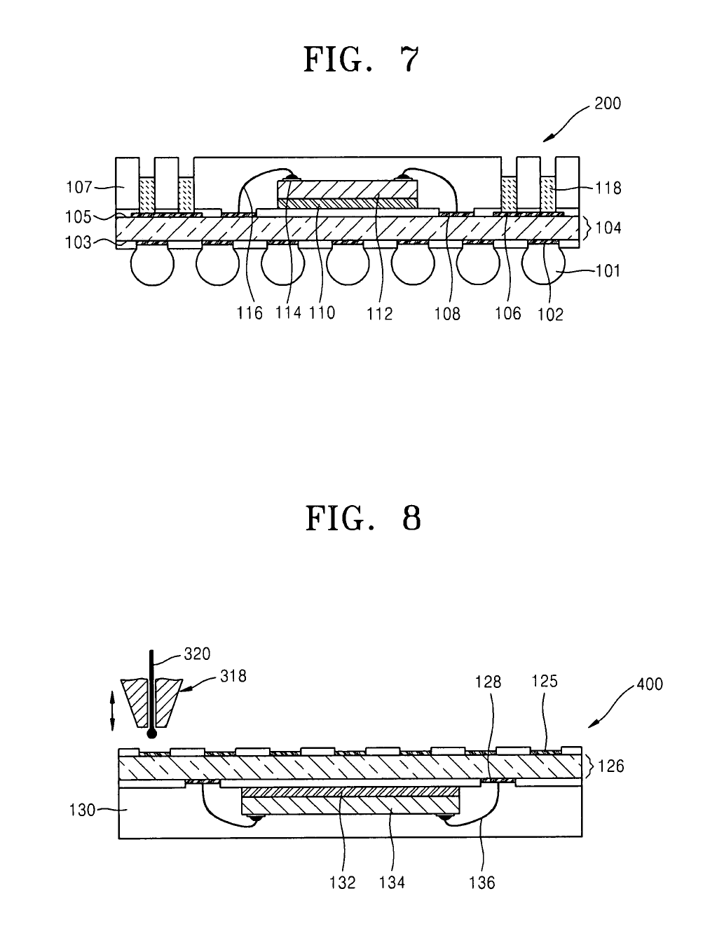

Referring to FIG. 7, the solder ball 101 may be disposed on the at least one substrate land 102 and may be thermally processed in order to electrically connect the solder ball 101 and the at least one substrate land 102. In example embodiments, the solder ball 101 may be formed after the at least one via-hole 140 is filled with the conductive member 118 (or 118a). Alternatively, the solder ball 101 may be formed after the first semiconductor package 200 and a second semiconductor package 400 are stacked together.

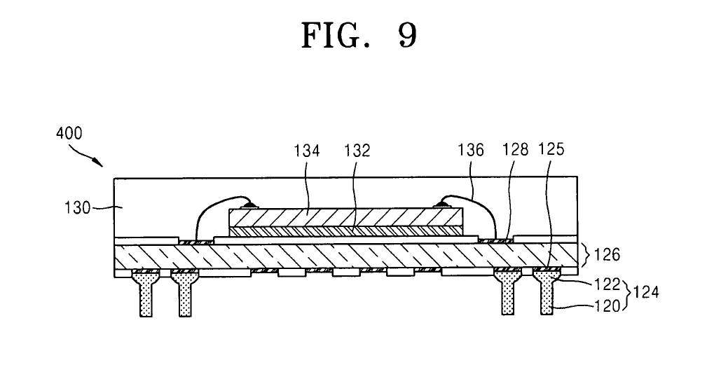

Referring to FIGS. 8 and 9, the second semiconductor package 400 may be prepared. For example, the second semiconductor chip 134 may be mounted on the second circuit board 126, and the second semiconductor chip 134 and the second circuit board 126 may be connected via the second wires 136. The second encapsulating member 130 may be formed on the second circuit board 126 to cover the second semiconductor chip 134 and the second wires 136. The resultant structure may be manufactured or may be purchased from an outside manufacturer.

The stud bump 124 may be formed on a substrate land 125 by using a capillary 318. For example, the stud bump 124 may formed by feeding a wire 320 through a capillary 318 and applying a relatively high voltage electric charge to an end of the wire 320 protruding from the capillary 318 to form a ball. The capillary 318 with the ball may be moved towards the substrate land 125 so that the ball is pressed against the substrate land 125 by the capillary 318 to form the bonding portion 122 of the stud bump 124. The protruding portion 120 of the stud bump 124 may be formed by moving the capillary 320, with the wire 320 threaded therein, a predetermined or preset distance away from the substrate land 125 in a direction substantially perpendicular to the substrate land 125. After the capillary 318 has been moved by the predetermined or preset distance, the wire 320 may be cut thereby forming the protruding portion 120 of the stud bump 124. The wire 320, for example, may be formed of a gold (Au) or nickel (Ni)-based material, e.g., gold (Au).

The second semiconductor package 400 may be stacked on the first semiconductor package 200 of FIG. 7. For example, the stud bump 124 may be inserted into the conductive member 118 and may be heated at about 100 to 600 degrees Celsius in order to connect the stud bump 124 and the conductive member 118, thereby manufacturing the stacked-type semiconductor package 100 of FIG. 1.

FIGS. 10A to 10C are perspective views of a stud bump according to example embodiments. Referring to FIG. 10A, the stud bump 124 may include a bonding portion 122 and a protruding portion 120. The bonding portion 122 may be formed by connecting the wire 320 to the substrate land 125. A part of the bonding portion 122 contacting the substrate land 125 may be referred to as a base part of the bonding portion 122. The protruding portion 120 may be formed by extending the wire 320 outwardly from the bonding portion 122. The diameter of the protruding portion 120 may be less than that of the bonding portion 122. The total number of the via-holes 104 in the first semiconductor package 200 of FIG. 7, into which a plurality of the protruding portion 120 may be inserted, may be increased by reducing the diameters of the protruding portions 120.

For example, the stud bump 124 may be obtained by performing a wire bonding operation using a capillary 318, moving the capillary 318 in the vertical direction toward the outside of the second semiconductor package 400 and then cutting the wire 320.

Referring to FIG. 10B, a stud bump 124′ may include a bonding portion 122′ and a protruding portion 120′. The protruding portion 120′ may include at least one convex portion 121 protruding widthwise to the protruding portion 120′. The convex portion 121 may have a ring shape. As illustrated in FIG. 1, when the stud bump 124′ is inserted into the conductive member 118, the stud bump 124′ may be tightly combined with the conductive member 118 via the convex portion 121, thereby increasing the connection strength between the stud bump 124′ and the conductive member 118. The stud bump 124′ may have a flat top surface. Thus, preventing or retarding the first semiconductor package 200 of FIG. 7 from being scratched when the stud bump 124′ contacts a top surface of the first semiconductor package 200 may be possible.

The bonding portion 122′ may be obtained by directly cutting the wire 320 without moving the capillary 318 in the vertical direction toward the outside of the second semiconductor package 400. Similarly, the protruding portion 120′ may be obtained by performing wire bonding on the bonding portion 122′ and cutting the wire 320. Forming the stud bump 124′ to have a predetermined or preset height may be possible by repeatedly performing the above process in consideration of the predetermined or preset height of the stud bump 124′.

Referring to FIG. 10C, a stud bump 124″ may include a bonding portion 122″ and a protruding portion 120″. The stud bump 124″ may be formed similar to the stud bump 124′ of FIG. 10B, except for an upper part of the stud bump 124″. Unlike the stud bump 124′, the stud bump 124″ may have a pointed upper part 123. The pointed upper part 123 may make it relatively easy for the stud bump 124″ to be inserted into the conductive member 118 of the first semiconductor package 200 of FIG. 7. Thus, during manufacturing of a stacked-type semiconductor package, even if the at least one via-hole 140 of the first semiconductor package 200 is slightly, erroneously aligned with respect to the at least one stud bump 124 of the second semiconductor package 400, the upper part 123 may allow for the at least one stud bump 124 to be easily inserted into the conductive member 118.

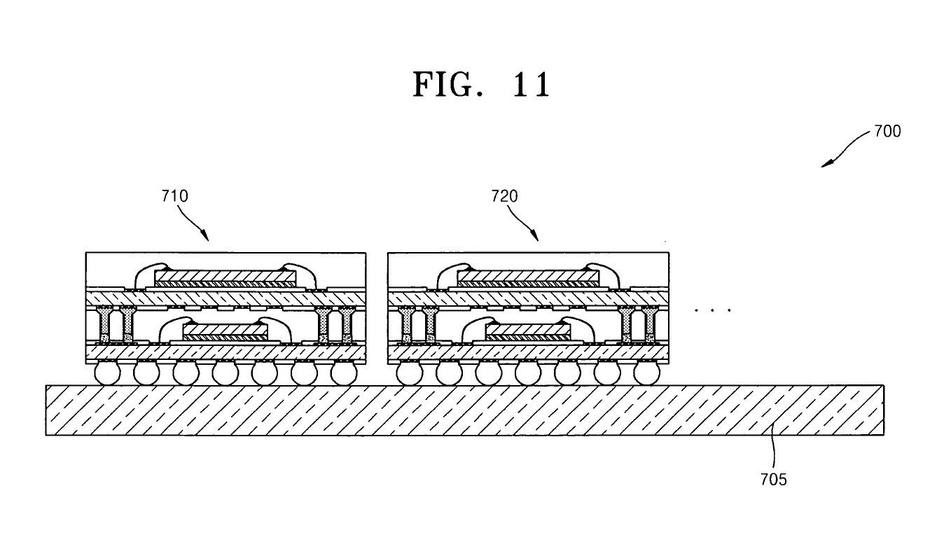

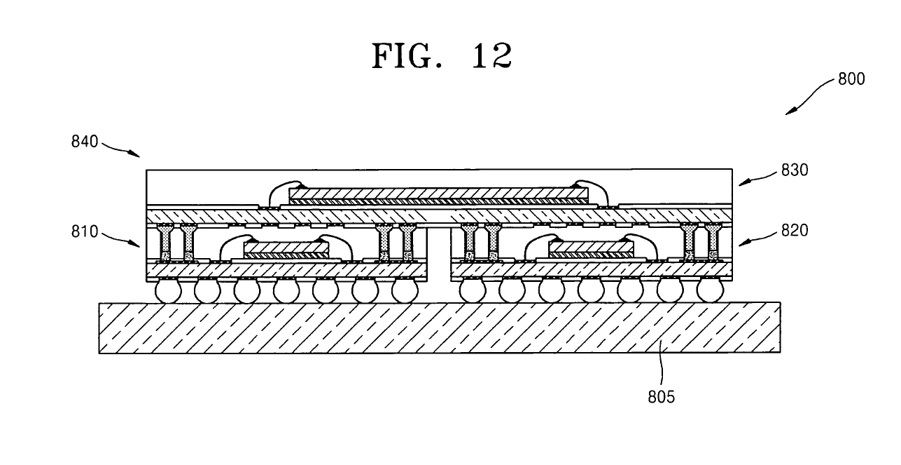

FIG. 11 is a schematic cross-sectional view of a semiconductor package module 700 according to example embodiments. Referring to FIG. 11, one or more semiconductor packages, e.g., a plurality of stacked-type semiconductor packages 710 and 720, may be stacked separately apart from each other on a module substrate 705 in the horizontal direction. The stacked-type semiconductor packages 710 and 720 may be identical to the stacked-type semiconductor package 100 of FIG. 1. However, each of the stacked-type semiconductor packages 710 and 720 may be replaced with the stacked-type semiconductor package 500 of FIG. 2 or the stacked-type semiconductor package 600 of FIG. 3. In the stacked-type semiconductor packages 710 and 720, solder balls may be connected to a module substrate 705, thereby enabling electrical signals to be exchanged between the stacked-type semiconductor packages 710 and 720 and the module substrate 705.

FIG. 12 is a schematic cross-sectional view of a semiconductor package module 800 according to example embodiments. Referring to FIG. 12, at least one stacked-type semiconductor package 840 may be mounted on a module substrate 805. The stacked-type semiconductor package 840 may include lower semiconductor packages 810 and 820 and an upper semiconductor package 830. The lower semiconductor packages 810 and 820 may be arranged apart from each other on the module substrate 805 in the horizontal direction, and the upper semiconductor package 830 may be stacked on the lower semiconductor packages 810 and 820.

The lower semiconductor packages 810 and 820 may substantially have the same construction as the first semiconductor package 200 of FIG. 1. The upper semiconductor package 830 may substantially have the same construction as the second semiconductor package 400 of FIG. 1. For example, the upper semiconductor package 830 may be constructed by combining a pair of the second semiconductor packages 400 of FIG. 1 in the horizontal direction, so that the upper semiconductor package 830 may be simultaneously connected to both of the lower semiconductor packages 810 and 820.

The semiconductor package module 800 may be constructed in a system-in-package (SIP) form, and may be used in a mobile device because the whole thickness of the semiconductor package module 800 may be reduced. For example, the upper semiconductor package 830 may include a logic chip, and the lower semiconductor packages 810 and 820 may include a memory chip.

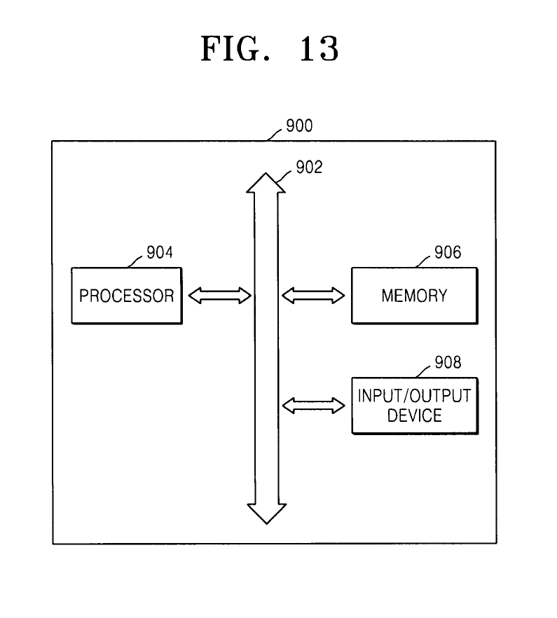

FIG. 13 is a block diagram of an electronic system 900 according to example embodiments. Referring to FIG. 13, data communication may be established among a processor unit 904, an input/output device 908, and a memory unit 906 via a bus 902. The processor unit 904 may execute a program and control the electronic system 900. The input/output device 908 may be used to input data to or output data from the electronic system 900. The electronic system 900 may be connected to an external device (not shown), e.g., a personal computer (PC), or the Internet via the input/output device 908 in order to exchange data with the external device.

Examples of the memory unit 906 may include the stacked-type semiconductor packages 100, 500, and 600 and the semiconductor package modules 700 or 800. For example, the memory unit 906 may store code and data necessary for operating the processor unit 904. The electronic system 900 may be used in mobile phones, MP3 players, navigation, solid state disks (SSDs), and/or household appliances.

While example embodiments have been particularly shown and described with reference to example embodiments thereof, it will be understood by those of ordinary skill in the art that various changes in form and details may be made therein without departing from the spirit and scope of the following claims.

What is claimed is:

1. A stacked-type semiconductor package comprising:
a first semiconductor package including a first encapsulating member having at least one first via-hole and at least one first conductive member in the at least one first via-hole; and
a second semiconductor package including at least one first stud bump, wherein the at least one first stud bump protrudes into the at least one first via hole to electrically connect the first semiconductor package and the second semiconductor package;
wherein the at least one first stud bump includes a bonding portion and a protruding portion extending from the bonding portion into the at least one first conductive member;
wherein the bonding portion is attached to a substrate land on the second semiconductor package;
wherein an area of a base part of the bonding portion connected to the substrate land is greater than an area of the protruding portion.

2. The stacked-type semiconductor package of claim 1, wherein the protruding portion includes at least one convex portion protruding widthwise to increase connection strength between the at least one first stud bump and the at least one first conductive member.

3. The stacked-type semiconductor package of claim 1, wherein the protruding portion is cylindrical and the bonding portion is hemispherical.

4. The stacked-type semiconductor package of claim 1, wherein the protruding portion includes a point.

5. The stacked-type semiconductor package of claim 1, wherein the at least one first conductive member is a resultant structure obtained by thermally processing one of solder paste and solder powder.

6. The stacked-type semiconductor package of claim 1, wherein a height of the at least one first conductive member is less than a height of the at least one first via-hole.

7. The stacked-type semiconductor package of claim 1, wherein the first semiconductor package includes
a circuit board with a first substrate pad, and
a chip on the circuit board, wherein the chip is electrically connected to the first substrate pad via one of at least one conductive wire and at least one through-via electrode.

8. The stacked-type semiconductor package of claim 1, further comprising:
a third semiconductor package including at least one second stud bump, wherein the second semiconductor package includes a second encapsulating member having at least one second via-hole and at least one second conductive member in the at least one second via-hole and the at least one second stud bump protrudes into the at least one second conductive member to electrically connect the third semiconductor package to the second semiconductor package.

9. The stacked-type semiconductor package of claim 1, further comprising:
a third semiconductor package including a second encapsulating member having at least one second via-hole and at least one second conductive member in the at least one second via-hole, wherein the second semiconductor package further includes at least one second stud bump protruding into the at least one second conductive member to electrically connect the third semiconductor package to the second semiconductor package.

10. The stacked-type semiconductor package of claim 9, wherein the first and third semiconductor packages are side by side and the second semiconductor package is on a top surface of the first semiconductor package and on a top surface of the third semiconductor package.

11. A semiconductor package module comprising:
a module substrate; and
the stacked-type semiconductor package of claim 1.

12. The semiconductor package module of claim 11, wherein the at least one first stud bump includes a bonding portion and a protruding portion extending from the bonding portion into the at least one first conductive member.

13. A semiconductor package module of claim 12, wherein the protruding portion includes at least one convex portion protruding widthwise to increase connection strength between the at least one first stud bump and the at least one first conductive member.
